(19) United States
(12) Patent Application Publication
(10) Pub. No.: US 2009/0277779 A1
(43) Pub. Date: Nov. 12, 2009

(54) MAGNETIC FIELD GENERATING APPARATUS, MAGNETIC FIELD GENERATING METHOD, SPUTTERING APPARATUS, AND METHOD OF MANUFACTURING DEVICE

(75) Inventor: Masao Sasaki, Hachioji-shi (JP)

Correspondence Address: FITZPATRICK CELLA HARPER & SCINTO, 1290 Avenue of the Americas, NEW YORK, NY, 10104-3800, US

(73) Assignee: CANON ANELVA CORPORATION, Kawasaki-shi (JP)

(21) Appl. No.: 12/463,084

(22) Filed: May 8, 2009

(30) Foreign Application Priority Data
May 12, 2008 (JP) 2008-124678
Apr. 24, 2009 (JP) 2009-106310

(51) Int. Cl. H01F 7/00; C23C 14/34

(52) U.S. Cl. 204/192.12; 335/296; 204/298.16

(57) ABSTRACT

A magnetic field generating apparatus includes a magnet assembly group including at least three magnet assemblies arranged along a straight line, each of the magnet assemblies including a permanent magnet, spilt yokes which are formed by magnetic members and are placed to surround the outer surface of the permanent magnet, and nonmagnetic members located between the yokes.

### BACKGROUND OF THE INVENTION

1. Field of the Invention

The present invention relates to a magnetic field generating apparatus and, more particularly, to a sputtering technique which uses a magnetron sputtering method of confining a plasma near a target by using a magnetic field and can be effectively applied to so-called magnetron sputtering.

2. Description of the Related Art

In a manufacturing process for electron devices, semiconductor devices, flat panel displays, and the like, film formation, surface treatment, and the like are performed for substrates. In this case, a sputtering method is widely used as a manufacturing technique.

The main stream of sputtering methods is magnetron sputtering in which magnets are placed on the rear surface side of a target which is an object to be processed. Magnetron sputtering is a method of forming a high-density plasma by forming a magnetic field on a target surface by using magnets, and confining the plasma near the target surface by using the drift motion of electrons. Making the high-density plasma existing near the target surface in this manner can implement high-speed film formation.

A magnetic field generating apparatus used in magnetron sputtering is generally formed by placing magnets on a yoke which is a plate-like magnetic member. In this case, the magnets located on the outer circumference and the magnets located inside have opposite polarities, and electrons are trapped near the target surface by the magnetic field generated between the two magnetic poles. As a consequence, erosion is formed between the magnetic poles on the target.

If a magnet is fixed to a target, erosion reflecting the shape of the magnet appears on the target. Although erosion occurs between the magnets located on the outer circumference and the magnets Located inside and having magnetic poles opposite to those of the magnets on the outer circumference. However, no erosion appears immediately above the magnets. For this reason, if a magnet is not moved, a region where no erosion appears (to be referred to as a non-erosion region hereinafter) exists on a portion of the target which is located immediately above the magnet.

Particles and the like are attracted to this non-erosion region, resulting in an increase in the number of particles on the substrate during film formation.

If a region where erosion appears is fixed, the target utilization ratio as the ratio of the volume of erosion to the volume of a target is low, resulting in uneconomical operation. In addition, it is difficult to form a film with a uniform thickness on the substrate.

For this reason, a conventional sputtering apparatus is configured to form a film while integrally moving magnets with a yoke relative to a target. The way of moving the magnets includes at least one of rotational motion and reciprocating motion. Moving the magnets relative to the target will eliminate non-erosion regions on the target and reduce the occurrence of particles. This also improves the target utilization ratio. As a consequence, the thickness uniformity of the formed film improves.

In recent sputtering film forming apparatuses for flat panel displays, however, larger targets are used. This requires large-scale mechanisms for moving magnets and complicated structures.

Japanese Patent Laid-Open Nos. 5-148642 and 2000-309867 disclose methods of moving an erosion region by using rod-like magnets and rotating them instead of moving all the magnets. These methods can simplify a mechanism for moving magnets even in a large-scale apparatus and reduce the size of the mechanism.

U.S. Pat. No. 5,399,253 and Japanese Patent Laid-Open Nos. 11-158625, 2007-204811, and 2001-32067 report methods of moving an erosion region on a target by combining fixed magnets and rotatably held rod-like magnets and rotating the rod-like magnets. These methods can also simplify a mechanism for moving magnets in a large-scale apparatus and reduce the size of the mechanism.

A case in which an erosion region is moved by rotating rod-like magnets will be described by using the case (see FIG. 11) disclosed in Japanese Patent Laid-Open No. 5-148642. The hatched portions in FIG. 11 are erosion regions 10 which appear on the target surface due to the drift motion of electrons trapped by magnetic lines of force 12. Rotating a plurality of rod-like magnets 3-1, 3-2, . . . , 3-10 can shift the positions of the drift motions of electrons indicated by the hollow arrows in FIG. 11 in the X direction.

In the portion indicated by “A” in FIG. 11, it is necessary to secure a certain gap between the magnets in the Y direction. In the portion indicated by “A” in FIG. 11, the N pole of a magnet 6-3 and the S pole of the magnet 3-3 form a magnetic field in the inverse Y direction. If the N and S poles of the magnets are close to each other, the magnetic flux density in the Y direction parallel to the target surface decreases on the target surface. This makes it difficult to maintain electric discharge.

The reason for this will be described with reference to FIGS. 12A and 12B. FIGS. 12A and 12B show the relationship between a magnetic field on the target surface and the gap between magnets. The magnetic field on the target surface is formed by the combination of the magnetic fields generated by the N and S poles (FIG. 12A). The strength of the composite magnetic field changes depending on the gap between magnets. If the magnets are extremely close to each other (FIG. 12B), the component of the composite magnetic field which is parallel to the target surface weakens.

In the portion indication by “A” in FIG. 11, it is necessary to secure a certain gap between the magnets in the Y direction.

In each portion indicated by “B” in FIG. 11, the magnet 3-1, 3-5, or 3-9 and the magnet 6-3 relative thereto have N polarity magnet 6-3. In this case, since the magnetic field generated by the magnet 3-1, 3-5, or 3-9 extends in a direction perpendicular to the drawing surface without reaching the magnet 6-3.

Therefore, electrons which have reached the portions indicated by “B” are ejected in a direction perpendicular to the drawing surface along the magnetic lines of force, and the drift motion of electrons does not form a closed loop. As a result, the state of the plasma near the target surface becomes unstable, and it is finally difficult to maintain electric discharge.

### SUMMARY OF THE INVENTION

The present invention provides a sputtering apparatus including a magnetic field generating apparatus which can solve the problem in the related art. For example, the present invention provides a sputtering apparatus including a magnetic field generating apparatus which stabilizes the state of plasma near a target surface and performs uniform sputtering.

According to one aspect of the present invention, there is provided a magnetic field generating apparatus comprising: a magnet assembly group including at least three magnet assemblies arranged along a straight line, each of the magnet assemblies including a permanent magnet, split yokes which are formed by magnetic members and are placed to surround an outer surface of the permanent magnet, and nonmagnetic members located between the yokes, wherein one or two or more adjacent magnet assemblies constituting one magnet assembly group exhibit one polarity on one surface side, a magnitude of a magnetic flux density on the one surface side which is generated by a surrounding magnet assembly which is adjacent to and surrounds the one or two or more adjacent magnet assemblies constituting the one magnet assembly group is smaller than a magnitude of a magnetic flux density on the one surface side which is generated by the one or two or more adjacent magnet assemblies constituting the one magnet assembly group, and the surrounding magnet assembly which is adjacent to and surrounds the one or two or more adjacent magnet assemblies constituting the one magnet assembly group is adjacent to and surrounded by a magnet assembly or a permanent magnet which exhibits a polarity on the one surface side which is opposite to a polarity of the one or two or more magnet assemblies constituting the one magnet assembly group.

According to another aspect of the present invention, there is provided a sputtering apparatus comprising: an above-mentioned magnetic field generating apparatus; target holding means, having one surface at which the magnetic field generating apparatus is placed, for holding a target on an opposite side to the one surface; and substrate holding means for holding a substrate at a position facing the target.

According to the present invention, the plasma state near a target surface can be further stabilized in magnetron sputtering.

Further features of the present invention will become apparent from the following description of exemplary embodiments with reference to the attached drawings.

### BRIEF DESCRIPTION OF THE DRAWINGS

FIG. 1 is a sectional schematic view showing a sputtering apparatus including a magnetic field generating apparatus according to the first embodiment of the present invention;

FIG. 2 is a view showing the detailed arrangement of the magnetic field generating apparatus in FIG. 1;

FIGS. 3A and 3B are sectional schematic views showing the structure of a magnetic assembly in FIG. 2;

FIG. 4 is a view showing a state in which magnet settings are changed by rotating rod-like magnets in the state in FIG. 2;

FIG. 5 is a view showing a state in which magnet settings are further changed by rotating rod-like magnets in the state in FIG. 4;

FIGS. 6A to 6C are plan views showing the states of the magnetic field generating apparatus shown in FIGS. 2, 4, and 5, respectively, when viewed from the target side;

FIGS. 7A to 7F are plan views each showing a magnetic field generating apparatus according to the second embodiment when viewed from the target side;

FIGS. 8A to 8D are plan views each showing a magnetic field generating apparatus according to the third embodiment when viewed from the target side;

FIG. 9 is a sectional schematic view showing magnet settings for magnet parts in the fourth embodiment;

FIGS. 10A to 10C are plan views each showing a magnetic field generating apparatus according to the fourth embodiment when viewed from the target side;

FIG. 11 is a plan view representatively showing the arrangement in patent reference 1 as a prior art which moves erosion by rotating rod-like magnets; and

FIGS. 12A and 12B are views for explaining a problem in a conventional arrangement like that shown in FIG. 11.

### DESCRIPTION OF THE EMBODIMENTS

The embodiments of the present invention will be described below with reference to the accompanying drawings

### First Embodiment

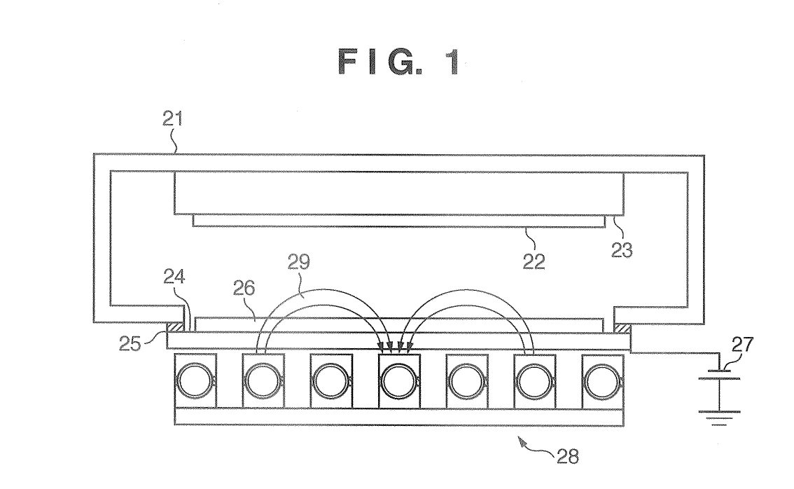

FIG. 1 is a sectional schematic view showing a sputtering apparatus including a magnetic field generating apparatus according to the first embodiment of the present invention. The sputtering apparatus shown in FIG. 1 includes a chamber 21 whose inside can be evacuated. A substrate holder 23 which holds a substrate 22 such as a wafer is placed in the chamber 21.

Although not shown, a pump for evacuation, a gas introduction unit, and the like are connected to the chamber 21.

An opening is formed in an inner wall portion of the chamber 21 which faces the substrate holder 23. A backing plate 24 is placed to seal this opening portion. The backing plate 24 is connected to the outer wall of the chamber 21 through a cathode insulating member 25.

A target 26 is placed on the backing plate 24 so as to face the substrate 22. Power is supplied from a power supply 27 to the target 26 via the backing plate 24.

A magnetic field generating apparatus 28 is placed on the side of the target 26 opposite to the substrate 22. The magnetic field generating apparatus 28 (also called a magnetron unit) forms a magnetic field indicated by magnetic lines of force 29 near the surface of the target 26 which is located on the substrate 22 side.

The magnetic field near the surface of the target 26 and the power supplied from the power supply 27 generate a high-density plasma between the target 26 and the substrate 22. This makes it possible to form a film on the substrate 22 by sputtering.

The magnetic field generating apparatus 28 will be described next.

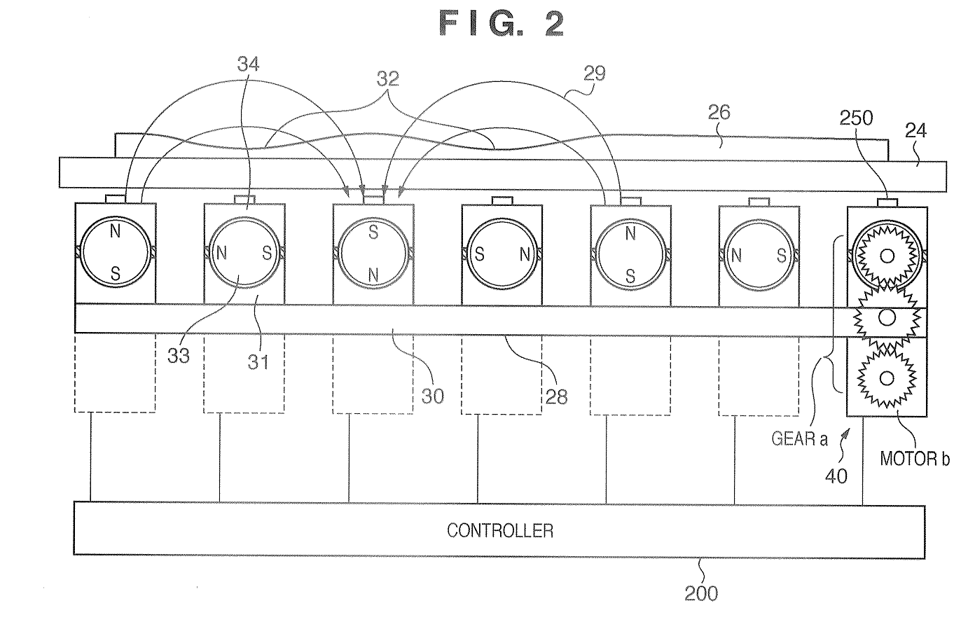

FIG. 2 shows the detailed arrangement of the magnetic field generating apparatus 28. Referring to FIG. 2, the target 26 is mounted on the backing plate 24. The upper surface of the target 26 is exposed to the inside of the chamber (not shown). The magnetic field generating apparatus 28 is placed on the opposite side to the surface of the backing plate 24 on which the target 26 is mounted.

The magnetic field generating apparatus 28 includes a yoke 30 made of a plate-like magnetic base member and a plurality of magnet assemblies (to be also referred to as “magnet parts 31” hereinafter). Each magnet assembly (magnet part 31) includes a rotatably supported permanent magnet (rod-like magnet 33), split yokes 34 which are made of magnetic members and placed to surround the outer surface of the permanent magnet, and nonmagnetic members 35 placed between the split yoke portions. A magnet assembly group (to be also referred to as a “magnet unit 36” hereinafter) is formed by arranging at least three magnet assemblies (magnet parts 31) along a straight line within the same plane.

The magnetic lines of force 29 formed between the N pole of each arbitrary magnet part 31 and the S pole of a corresponding one of the magnet parts 31 alternately arranged from the arbitrary magnet part form a tunnel-like curve near the surface of the target 26. An erosion region 32 is formed on the surface of the target 26 centered on a portion where the magnetic lines of force 29 are parallel to the surface of the target 26.

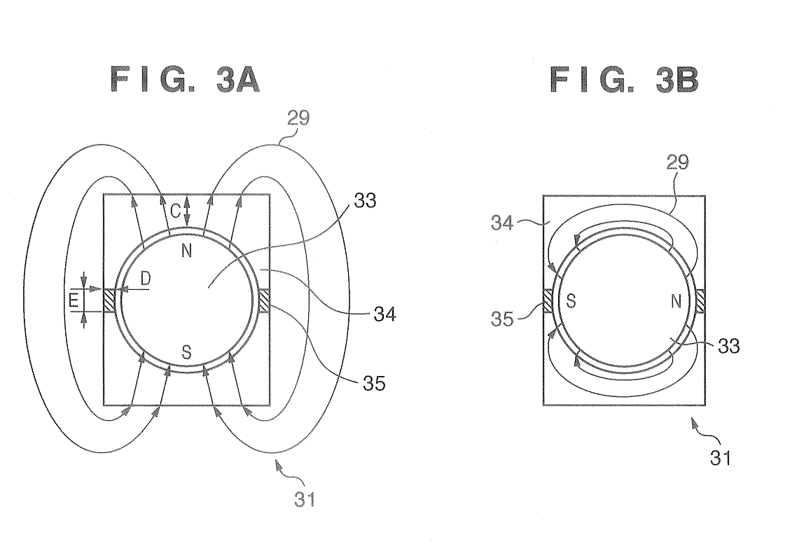

The arrangement of the magnet part 31 will be described in detail below. FIGS. 3A and 3B are sectional schematic views showing the structure of the magnet part 31.

The magnet part 31 is formed by using the rod-like magnet 33, the yoke 34 which surrounds the magnet, and the nonmagnetic members 35.

The rod-like magnet 33 is, for example, a permanent magnet formed in a cylindrical shape. The magnetization direction of the rod-like magnet 33 defines a tilt angle with a plane passing through the center axis of the cylinder. Preferably, the magnetization direction is perpendicular to a plane passing through the axis of the cylinder. The rod-like magnet 33 can rotate about its center axis.

The yokes 34 are made of magnetic members as two split portions. These two portions each have a concave surface having a curvature radius slightly larger than the curvature radius of the cylindrical outer surface of the rod-like magnet 33.

The rod-like magnet 33 is placed with a gap being secured between the concave surfaces of the two portions. The cylindrical outer surface of the rod-like magnet 33 is surrounded by the concave surfaces of the two portions. The two portions are connected through the nonmagnetic members 35.

Note, however, that the curvature radius of the yoke 34 need not always be larger than that of the cylindrical outer surface of the rod-like magnet 33 as long as the rod-like magnet 33 can rotate relative to the yoke 34.

Such a magnet structure is basically the same as that of the magnet chuck disclosed in Japanese Patent Laid-Open No. 7-94321.

In the above arrangement of the magnet part 31, as shown in FIG. 3A, when the magnetic poles of the rod-like magnet 33 point in the vertical direction (a direction perpendicular to the target surface), the magnetic lines of force 29 emerge from the N pole of the rod-like magnet 33 to the outside through the yoke 34, pass through the yoke 34 again, and run to the S pole of the rod-like magnet 33. This state is the same as that of a general magnet, and will be referred to as an “ON state” hereinafter.

In contrast, as shown in FIG. 3B, when the magnetic poles of the rod-like magnet 33 point in the horizontal direction, the magnetic lines of force 29 emerging from the rod-like magnet 33 return to the rod-like magnet 33 through the yoke 34 and do not run to the outside of the yoke 34. At this time, the magnet part 31 does not form a magnetic field with a magnetic flux density high enough to trap electrons on the target. This state will be referred to as an “OFF state” hereinafter.

The yoke 34 (portion C) needs to have a thickness large enough to allow a magnetic flux to pass when the magnet is in the OFF state.

If the portion C is thin, magnetic saturation occurs in the portion C to cause the magnetic lines of force 29 to emerge to the outside space of the yoke 34, resulting in a decrease in the effect of the OFF state. In a general sputtering apparatus, setting the thickness of the portion C to 10 mm or more can implement the OFF state without causing magnetic saturation. In this embodiment, the thickness of the portion C is set to 10 mm.

The portions (the portions indicated by sizes D and E in FIG. 3A) which connect the two split portions to form the yoke 34 will be described next.

In these portions, the nonmagnetic members 35 which connect the two portions constituting the yoke 34 are arranged. The portions are important in forming the ON state and OFF state of the magnet.

When the magnet is in the ON state, it is preferable that the magnetic lines of force 29 passing through the yoke 34 leak to the outside space of the yoke 34. This is because the magnetic field in the space increases in strength, and electrons can be effectively trapped. However, the magnetic lines of force 29 easily pass through the yoke 34 as a magnetic member, and return to the magnet through the yoke 34 without emerging to the outside space of the yoke 34 through the nonmagnetic members 35.

For this reason, in consideration of a magnetic circuit, it is necessary to form a magnetic resistance in the yoke 34 to suppress the number of magnetic lines of force 29 which return to the magnet through the yoke 34. The magnetic resistance increases as the size D decreases and the size E increases.

If, however, the magnetic resistance is increased by decreasing the size D and increasing the size E excessively, the magnetic lines of force 29 which emerge from the magnet when the magnet is in the OFF state directly emerge to the outside space of the yoke 34 without being through the yoke 34. This makes it impossible to implement a sufficient OFF state. For this reason, the sizes D and E which provide a proper magnetic resistance are important.

Magnetic field analysis revealed that when the size D was 1 mm, a weak magnetic field was formed in the outside space of the yoke 34 even while the magnet was in the OFF state, and hence a sufficient OFF state was not set. When the size D was 2 mm or more, the OFF state of the magnet was sufficiently maintained. That is, this size was effective. Note, however, that as the size D increases, a magnetic field in the outside space of the yoke 34 when the magnet is in the ON state weakens.

It was found that the width E of the nonmagnetic member 35 was preferably 9 mm or less. When the size E was larger than 10 mm, a weak magnetic field is formed in the outside space of the yoke 34 even while the magnet is in the OFF state, and hence a sufficient OFF state was not set.

As the size E decreases, therefore, a magnetic field in the outside space of the yoke 34 when the magnet is in the ON state weakens. However, this change is moderate. Therefore, no problem arises when the size E is 9 mm or less.

In this embodiment, the sizes D and E are respectively set to 2 mm and 5 mm to maximize the magnetic field strength in the ON state while implementing a sufficient OFF state.

Note that the sizes D and E are sizes relative to the yoke 34, and the nonmagnetic member 35 need not always have the above sizes. Important sizes are the size D of the portion which a magnetic field enters and the size E of the portion through which a magnetic field passes. The size of the nonmagnetic member 35 itself is not at issue. The two portions constituting the yoke 34 are attracted to each other by magnetic force. The nonmagnetic members 35 serve to maintain the positions of the two portions against the force.

The magnetic field generating apparatus 28 having the magnet parts 31 described above will be described by referring back to FIG. 2.

Referring to FIG. 2, the seven magnet parts 31 are arranged side by side on the yoke 30. A rotating mechanism 40 connected to a motor b through gears a can axially rotate the rod-like magnet 33 of each magnet part 31. FIG. 2 representatively shows the gears a and the motor b only in the rod-like magnet 33 on the right end in FIG. 2.

A magnetic sensor 250 is placed on a portion of the yoke 34 of each magnet part 31 which faces the target 26. The magnetic sensor 250 can detect magnetic field information (e.g., a magnetic flux density) on the side facing the target 26. A controller 200 can control the rotation of each rod-like magnet 33 by controlling the rotation of the motor b of the rotating mechanism 40 in accordance with the signal detected by the magnetic sensor 250. FIG. 2 representatively shows the controller 200 and the magnetic sensors 250.

The rod-like magnets 33 of the respective arrayed magnet parts 31 have different magnetization directions, respectively.

Referring to FIG. 2, when the leftmost magnet part 31 is in the ON state and acts as an N-pole magnet against the target 26, the second magnet part 31 from the left is in the OFF state. When the third magnet part 31 from the left is in the ON state and acts as an S pole against the target 26, the fourth magnet part 31 from the left is in the OFF state. When the fifth magnet part 31 from the left is in the ON state and acts as an N pole against the target 26, the sixth and seventh magnet parts from the left are in the OFF state.

That is, in the state shown in FIG. 2, the first and fifth magnet parts 31 from the left in FIG. 2 act as N poles against the target 26, and the third magnet part 31 from the left in FIG. 2 acts as an S pole against the target 26. The magnetic lines of force 29 are formed between magnet parts acting as N and S poles against the target 26. Other magnet parts in the OFF state do not contribute to the formation of a magnetic field.

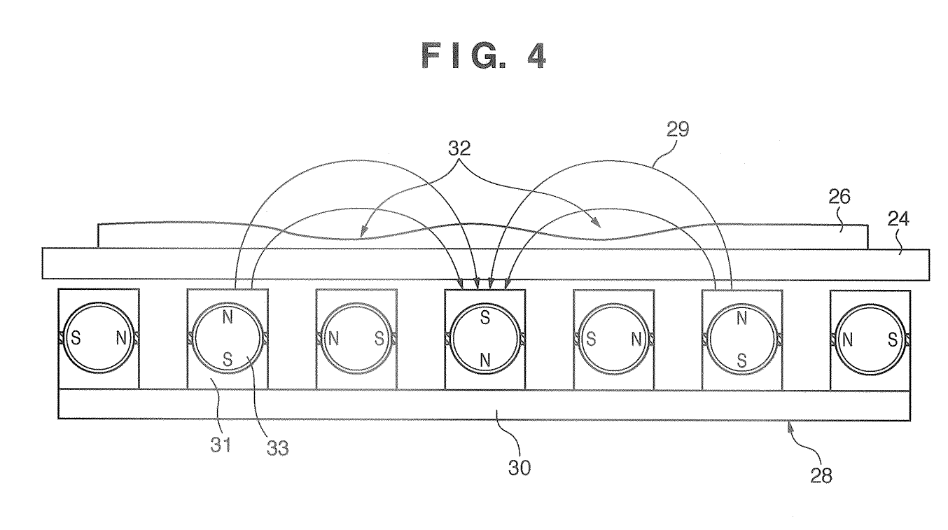

A case in which the state in FIG. 2 is changed to the state in FIG. 4 by rotating the rod-like magnets 33 will be described next.

Referring to FIG. 4, when the second and sixth magnet parts 31 from the left are in the ON state and act as N poles against the target 26, the fourth magnet part 31 from the left acts as an S pole against the target 26 in the ON state. The remaining magnet parts 31 are in the OFF state.

At this time, the magnetic lines of force 29 are formed as indicated by the arrows in FIG. 4, and the erosion regions 32 are formed on the surface of the target 26 centered on portions where the magnetic lines of force 29 become parallel to the surface of the target 26. As compared with FIG. 2, the positions of the erosion regions 32 have moved to the right in FIG. 4.

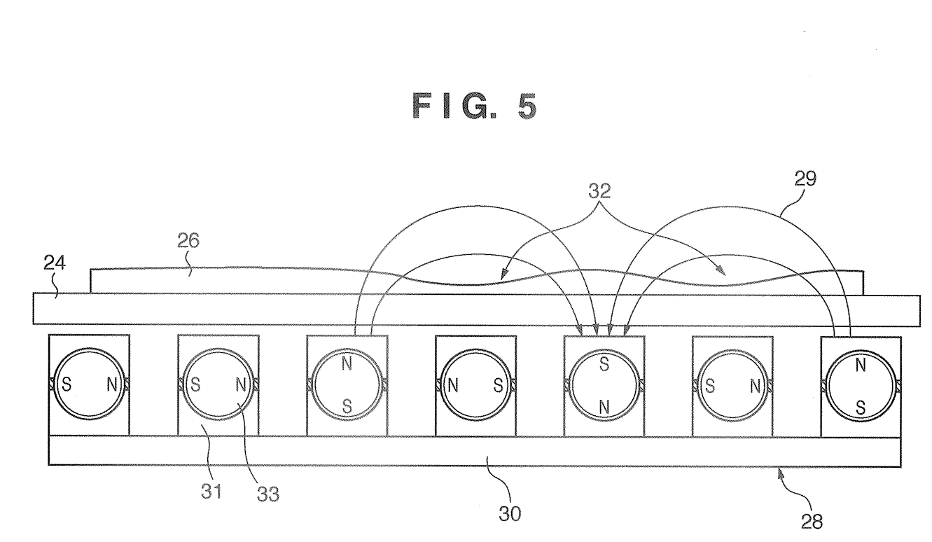

A case in which the state in FIG. 4 is changed to the state in FIG. 5 by rotating the rod-like magnets 33 will be described next.

Referring to FIG. 5, when the third and seventh magnet parts 31 from the left are in the ON state and act as N poles against the target 26, the fifth magnet part 31 from the left is in the ON state and acts as an S pole against the target 26. The remaining magnet parts 31 are in the OFF state.

At this time, the magnetic lines of force 29 are formed as indicated by the arrows in FIG. 5, and the erosion regions 32 are formed on the surface of the target 26 centered on the portions where the magnetic lines of force 29 become parallel to the surface of the target 26. As compared with FIG. 4, the positions of the erosion regions 32 have further moved to the right in FIG. 5.

As described based on FIGS. 2, 4, and 5, it is possible to move the erosion regions 32 on the target 26 by changing the ON state and OFF state of the magnets by rotating the rod-like magnets 33 of the magnet parts 31 arranged side by side along the rear surface of the target 26. In addition, repeating a series of operations of changing the state in FIG. 2 to the state in FIG. 4, changing the state in FIG. 4 to the state in FIG. 5, changing the state in FIG. 5 to the state in FIG. 4, and changing the state in FIG. 4 to the state in FIG. 2 will eliminate non-erosion portions on the target 26 and form almost uniform erosion on the entire surface of the target 26.

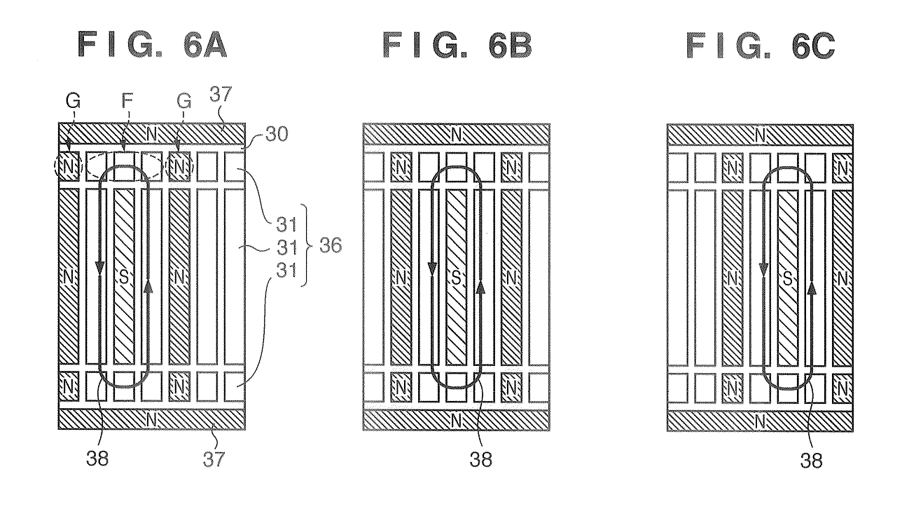

FIGS. 6A to 6C are plan views each showing the magnetic field generating apparatus 28 when viewed from the target 26 side. More specifically, FIGS. 6A, 6B, and 6C respectively correspond to the states in FIGS. 2, 4, and 5.

As shown in FIGS. 6A to 6C, the magnetic field generating apparatus 28 has a plurality of (seven in FIGS. 6A to 6C) magnet units 36 arranged parallel on the plate-like yoke 30.

Each magnet unit 36 is a magnet part group constituted by three magnet parts 31. The three magnet parts 31 of each magnet unit 36 are arranged in a straight line in the vertical direction (the center axis direction of the rod-like magnet) in FIGS. 6A to 6C. Each magnet part 31 is provided with the rotating shaft of the rod-like magnet 33 (not shown) along the longitudinal direction (the vertical direction in FIGS. 6A to 6C) of the magnet part 31. The rotation of the rod-like magnet 33 of each magnet part 31 can be independently controlled. In this case, since the magnet parts 31 are arranged side by side in a straight line, the rod-like magnet 33 of each magnet part 31 can be independently rotated. It is therefore unnecessary to arrange the respective magnet parts 31 in a straight line in a geometrical sense. That is, it suffices if they look arranged in a straight line. The usage of this term is consistent throughout this specification, the appended claims, and the drawings. In addition, the manner of arranging the magnet parts in a straight line as described above is expressed that “the magnet parts are arrayed in a straight line”.

In each of the magnet unit 36, the magnet part 31 at the middle is longer than the magnet parts 31 at the two ends.

In addition, oblong magnets (long magnets) 37 are located at the two ends in the array direction of the magnet parts of each magnet unit 36 (the vertical direction in FIGS. 6A to 6C) so as to extend throughout the plurality of magnet units 36. The magnets 37 do not move and act as N-pole magnets against the target 26.

Note that in FIGS. 6A to 6C, “N” is written on each magnet part 31 acting as an N pole against the target in the ON state, and “S” is written on each magnet part 31 acting as an S pole against the target in the ON state. Each magnet part 31 on which nothing is written is in the OFF state.

Referring to FIG. 6A, all the magnet parts 31 constituting the magnet units 36 on the first and fifth columns from the left are set to act as N poles against the target in the ON state.

At this time, the long magnet part 31 located at the middle of the magnet unit 36 on the third column from the left is set to act as an S pole against the target in the ON state. In addition, the respective magnet parts 31 which are adjacent to and surround the S pole are set in the OFF state. That is, the two short magnet parts 31 located at the two ends of the magnet unit 36 on the third column from the left and all the magnet parts 31 constituting the magnet units 36 on the second and fourth columns from the left are in the OFF state. The remaining magnet parts 31, except for the fixed magnets 37, are in the OFF state.

When the respective magnets are set in the above states, the drift motion of electrons occurs between the S pole and the N poles surrounding it so as to form a closed loop, as indicated by a thick arrow 38 in FIG. 6A.

More specifically, the short magnet parts 31 at the two ends of each of the magnet units 36 on the second to fourth columns from the left are set in the OFF state so as not to interfere with the drift motion 38 of electrons. In addition, since a sufficient gap (e.g., a portion F in FIG. 6A) can be secured between the N pole of the fixed oblong magnet 37 and the S pole of the long magnet part 31 at the middle of the magnet unit 36 on the third column from the left because the short magnet part 31 is placed, it is possible to form a strong magnetic field in the portion F in a direction parallel to the target surface.

Furthermore, the short magnet parts 31 placed in gaps (e.g., portions G in FIG. 6A) between the N pole of the fixed oblong magnet 37 and the N poles of the long magnet parts 31 at the middle of the magnet units 36 on the first and fifth columns from the left are set to act as N poles against the target in the ON state. This can prevent electrons in drift motion indicated by the thick arrow 38 in FIG. 6A from leaking out of the magnets through the portions G.

Among five adjacent magnet assembly groups of a plurality of magnet assembly groups, e.g., six or more magnet assembly groups, (i) one or two or more adjacent magnet assemblies constituting one magnet assembly group exhibit one polarity on one surface side, (ii) the magnitude of magnetic flux density generated on one surface side by a surrounding magnet assembly which is adjacent to and surrounds one or two or more adjacent magnet assemblies constituting one magnet assembly group is smaller than that on one surface side which is generated by one or two or more magnet assemblies constituting one magnet assembly group, and (iii) a surrounding magnet assembly which surrounds one or two or more adjacent magnet assemblies constituting one magnet assembly group is adjacent to and surrounded by a magnet assembly or a permanent magnet exhibiting a polarity, on one surface side, which is opposite to the polarity of one or two or more adjacent magnet assemblies constituting one magnet assembly. The cross relationship between magnetic fields is maintained by (i), (ii), and (iii).

With the above magnet settings, the drift motion of electrons in the closed loop indicated by the thick arrow 38 in FIG. 6A occurs, and erosion is formed on the target 26 along the loop. When the drift motion of electrons becomes a closed loop, stable electric discharge can be obtained, and a high-density plasma can be formed. This makes it possible to form a film at high speed.

A case in which the state of the magnet parts 31 in FIG. 6A is changed to the state in FIG. 6B will be described next.

Referring to FIG. 6B, all the magnet parts 31 constituting the magnet units 36 on the second and sixth columns from the left are set to act as N poles against the target 26 in the ON state.

At this time, the long magnet part 31 located at the middle of the magnet unit 36 on the fourth column from the left is set to act as an S pole against the target 26 in the ON state. The adjacent magnet parts 31 surrounding the S pole are set in the OFF state. That is, the two short magnet parts 31 located at the two ends of the magnet unit 36 on the fourth column from the left and all the magnet parts 31 constituting the magnet units 36 on the third and fifth columns from the left are in the OFF state. The remaining magnet parts 31, except for the fixed magnets 37, are in the OFF state.

When the respective magnets are set in this manner, a magnetic field in which the drift motion of electrons occurs moves to the right in FIG. 6B, thereby moving the erosion region on the target 26, as compared with the state in FIG. 6A. In this state as well, the drift motion of electrons forms a closed loop for the same reason as that described above.

A case in which the state of the magnet part 31 in FIG. 6B is changed to the state in FIG. 6C will be described further.

Referring to FIG. 6C, all the magnet parts 31 constituting the magnet units 36 on the third and seventh columns from the left are set to act as N poles against the target in the ON state.

At this time, the long magnet part 31 located at the middle of the magnet unit 36 on the fifth column from the left is set to act as an S pole against the target in the ON state. In addition, the respective magnet parts 31 which are adjacent to and surround this S pole are set in the OFF state. That is, the two short magnet parts 31 located at the two ends of the magnet unit 36 on the fifth column from the left and all the magnet parts 31 constituting the magnet units 36 on the fourth and sixth columns from the left are in the OFF state. The remaining magnet parts 31, except for the fixed magnets 37, are in the OFF state.

When the respective magnets are set in this manner, a magnetic field in which the drift motion of electrons occurs further moves to the right in FIG. 6C, thereby moving the erosion region on the target 26, as compared with the state in FIG. 6B.

In addition, an erosion region is almost uniformly formed on the entire surface of the target 26 by repeating the movement of the position of the erosion region on the target 26 in the order of the state shown in FIG. 6A→the state shown in FIG. 6B→the state shown in FIG. 6C→the state shown in FIG. 6B→the state shown in FIG. 6A→the state shown in FIG. 6B→the state shown in FIG. 6C→ . . . . In this case, properly changing the holding times of the states shown in FIGS. 6A to 6C can further improve the uniformity of erosion.

Although the above description has exemplified the case in which N poles are set to surround an S pole, the same effect as that described above can be obtained by reversing the polarities. In the embodiment described later, the polarities can also be reversed.

A film formation sequence in the sputtering apparatus including the above magnetic field generating apparatus will be described next.

After the chamber 21 of the sputtering apparatus shown in FIG. 1 is evacuated, the substrate 22 is transferred into the chamber 21 and held on the substrate holder 23 so as to face the target 26. As the target 26, for example, an aluminum target is used. A process gas is introduced into the chamber 21. As a consequence, a predetermined pressure is set in the chamber 21. As a process gas, for example, argon gas is used.

Subsequently, the magnetic field generating apparatus 28 placed on the rear surface of the target 26 operates in the magnet setting sequence shown in FIGS. 2, 4, 5, and 6A to 6C.

For example, in the set state in FIG. 2 and 6A, the power supply 27 supplies power to the target 26. The supplied power is DC power or the like. As a result, electric discharge occurs in the chamber 21, and the target 26 is sputtered to deposit an aluminum film on the substrate 22.

After a predetermined period of time of film formation, the sputtering apparatus rotates the magnets on each column in the magnetic field generating apparatus 28 to set the state in FIGS. 4 and 6B. In this set state, the apparatus sputters the target 26 to form a film on the substrate 22. In addition, after a predetermined period of time of film formation, the sputtering apparatus rotates the magnets on each column in the magnetic field generating apparatus 28 to set the state in FIGS. 5 and 6C. In this set state, the apparatus sputters the target 26 to form a film on the substrate 22.

In this manner, the apparatus continues film formation while moving an erosion region on the target 26 by changing the magnet settings in the magnetic field generating apparatus 28.

After a predetermined period of time of film formation, the supply of power, the operation of the magnetic field generating apparatus 28, and the supply of a process gas are stopped, and the chamber 21 is evacuated.

Finally, the substrate 22 is unloaded from the chamber 21.

Moving an erosion region in this manner can eliminate non-erosion regions on the target 26 and suppress the generation of particles in film formation. Furthermore, this can make erosion uniform and increase the target utilization ratio, thereby improving the uniformity of a film.

### Second Embodiment

As shown in FIGS. 6A to 6C, if an erosion region is moved only in one direction (the horizontal direction in FIGS. 6A to 6C), the target 26 may be excessively eroded by erosion overlaps at end portions of an erosion region in the vertical direction in FIGS. 6A to 6C. In this case, the target utilization ratio decreases. In order to prevent such a situation, it is preferable to move an erosion region in the vertical direction in FIGS. 6A to 6C as well as the horizontal direction in FIGS. 6A to 6C.

A form in this case will be described as the second embodiment.

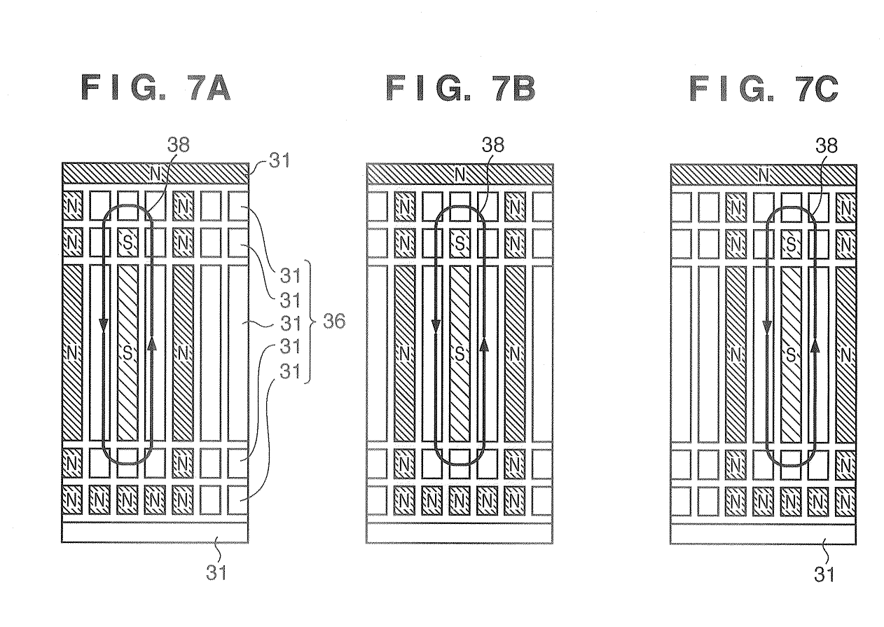

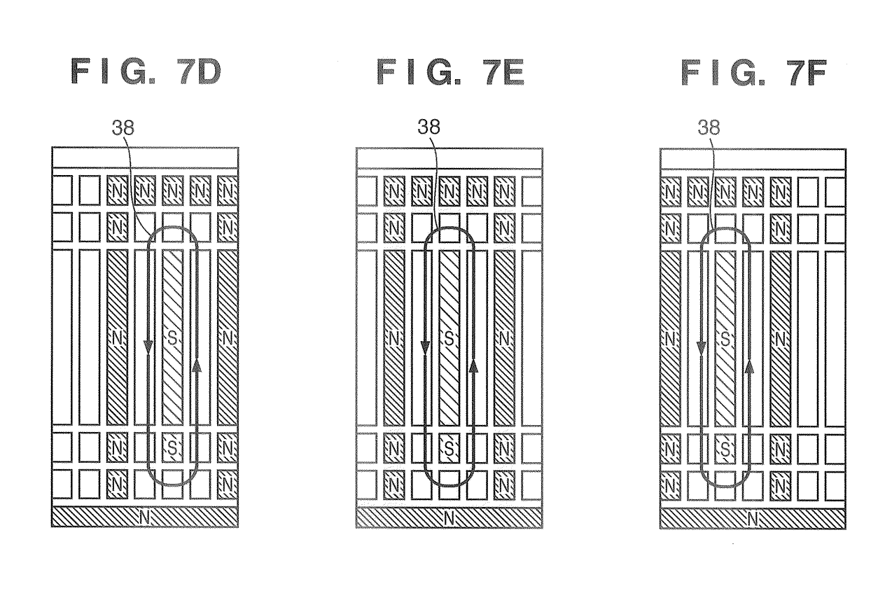

FIGS. 7A to 7F are plan views each showing a magnetic field generating apparatus 28 according to the second embodiment when viewed from the target 26 side. More specifically, FIGS. 7A and 7F correspond to the state in FIG. 2, FIGS. 7B and 7E correspond to the state in FIG. 4, and FIGS. 7C and 7D correspond to the state in FIG. 5.

The magnetic field generating apparatus 28 shown in FIGS. 7A to 7F has a plurality of (seven in FIGS. 7A to 7F) magnet units 36 arranged parallel on a plate-like yoke 30 as in the first embodiment.

In the second embodiment, each magnet unit 36 is a magnet part group constituted by five magnet parts 31. The five magnet parts 31 of each magnet unit 36 are arranged in a straight line in the vertical direction (the center axis direction of the rod-like magnet) in FIGS. 7A to 7F. Each magnet part 31 is provided with the rotating shaft of a rod-like magnet (not shown) along the longitudinal direction (the vertical direction in FIGS. 7A to 7F) of the magnet part 31.

The structure of each magnet part 31 is the same as that in the first embodiment (see FIGS. 3A and 3B).

In each magnet unit 36, the magnet part 31 longer than the remaining magnet parts is placed at the middle, and the magnet parts 31 shorter than the magnet part 31 at the middle are arranged in two at the two ends of the magnet part at the middle.

In addition, oblong magnets are located at the two ends in the array direction of the magnet parts of each magnet unit 36 (the two ends in the vertical direction in FIGS. 7A to 7C) so as to extend throughout the plurality of magnet units 36. These magnets are also the magnet parts 31. The magnets are also provided with the rotating shafts of rod-like magnets (not shown) along the horizontal direction in FIGS. 7A to 7F.

Note that in FIGS. 7A to 7F, “N” is written on each magnet part 31 acting as an N pole against the target in the ON state, and “S” is written on each magnet part 31 acting as an S pole against the target in the ON state. Each magnet part 31 on which nothing is written is in the OFF state.

Referring to FIG. 7A, the long magnet part 31 located at the middle of the magnet unit 36 on the third column from the left and the short magnet part 31 located on the upper side in FIG. 7A are set to act as S poles against the target in the ON state. At this time, the respective magnet parts 31 which are adjacent to and surround these S poles are set in the OFF state.

In addition, the magnet parts 31 which are adjacent to and surround the magnet parts 31 in the OFF state are N poles in the ON state. That is, all the magnet parts 31 constituting the magnet units 36 on the first and fifth columns from the left, the second lowermost magnet parts 31 of the magnet units 36 on the second to fourth columns from the left, and the oblong magnet part 31 on the upper side in FIG. 7A are set to act as N poles against the target in the ON state. The remaining magnet parts 31 are in the OFF state.

Setting the respective magnets in this state will cause the drift motion of electrons between the S poles and the N poles surrounding the S poles so as to form a closed loop, as indicated by a thick arrow 38 in FIG. 7A. Erosion is formed on the target 26 along this loop.

The magnet settings of the magnet parts 31 are sequentially changed as shown in FIGS. 7B and 7C to move, to the right in FIG. 7A, the state in which some magnets act as S poles and other magnets surrounding them act as N poles against the target. As a consequence, as indicated by the thick arrows 38 in FIGS. 7B and 7C, the closed loop of the drift motion of electrons moves to the right in FIGS. 7B and 7C.

Subsequently, as shown in FIG. 7D, the long magnet part 31 located at the middle of the magnet unit 36 on the fifth column from the left and the short magnet part 31 located on the lower side in FIG. 7D are set to act as S poles against the target in the ON state. At this time, the respective magnet parts 31 which are adjacent to and surround these S poles are set in the OFF state.

In addition, the magnet parts 31 which are adjacent to and surround the magnet parts 31 in the OFF state are N poles in the ON state. That is, all the magnet parts 31 constituting the magnet units 36 on the third and seventh columns from the left, the second uppermost magnet parts 31 of the magnet units 36 on the fourth to sixth columns from the left, and the oblong magnet part 31 on the lower side in FIG. 7D are set to act as N poles against the target in the ON state. The remaining magnet parts 31 are in the OFF state.

In the case in FIG. 7D, the closed loop of the drift motion of electrons moves to the lower side in FIG. 7D as compared with the case in FIG. 7C, as indicated by the arrow 38 in FIG. 7D.

The magnet settings of the magnet parts 31 are sequentially changed as shown in FIGS. 7E and 7F to move, to the left in FIGS. 7E and 7F, the state in which some magnets act as S poles and other magnets surrounding them act as N poles against the target. As a consequence, as indicated by the thick arrows 38 in FIGS. 7E and 7F, the closed loop of the drift motion of electrons moves to the left in FIGS. 7E and 7F.

Subsequently, the above state returns to the state in FIG. 7A, and the states in FIGS. 7A to 7F are repeatedly set.

Changing the set state of the magnets in this manner will reduce the overlaps of end portions of an erosion region in the vertical direction in FIGS. 7A to 7F and eliminate any places on the target 26 where excessive erosion occurs, thereby improving the target utilization ratio.

### Third Embodiment

The third embodiment will be described next.

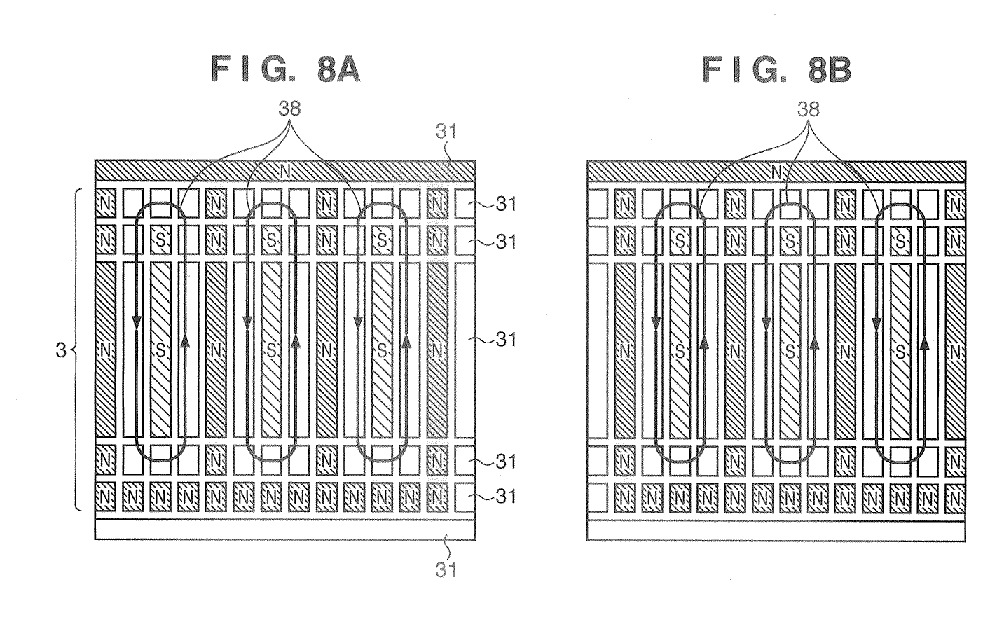

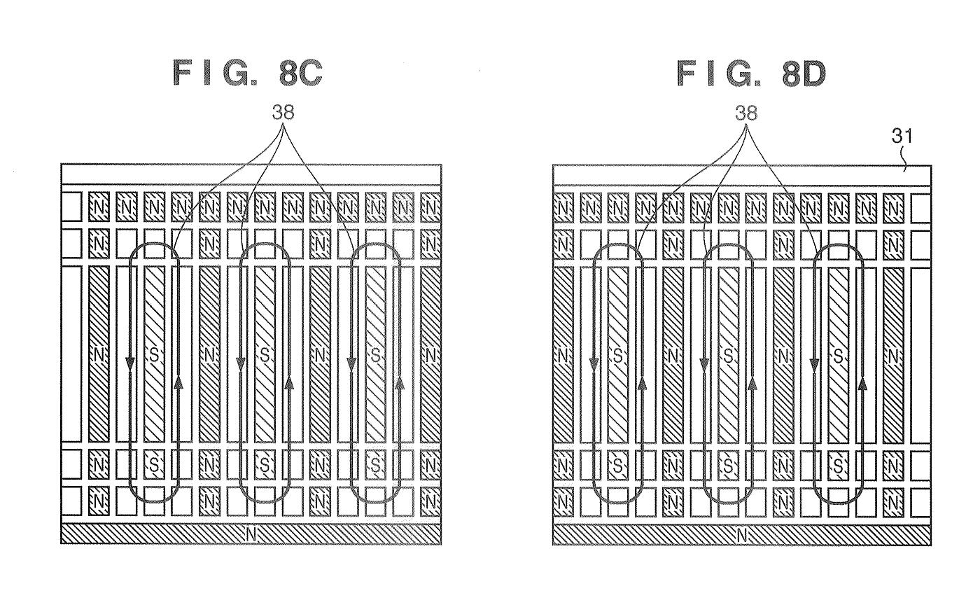

FIGS. 8A to 8D are plan views each showing a magnetic field generating apparatus 28 according to the third embodiment when viewed from the target 26 side.

In the magnetic field generating apparatus 28 shown in FIGS. 8A to 8D, a larger number (14 in FIGS. 8A to 8D) of magnet units 36 than in the second embodiment are arranged parallel on a plate-like yoke 30.

As in the second embodiment, each magnet unit 36 is a magnet part group constituted by five magnet parts 31. The five magnet parts 31 of each magnet unit 36 are arranged in a straight line in the vertical direction (the center axis direction of the rod-like magnet) in FIGS. 8A to 8D. Each magnet part 31 is provided with the rotating shaft of a rod-like magnet (not shown) along the longitudinal direction (the vertical direction in FIGS. 8A to 8D) of the magnet part 31.

The structure of each magnet part 31 is the same as that in the first embodiment (see FIGS. 3A and 3B).

In each magnet unit 36, the magnet part 31 longer than the remaining magnet parts is placed at the middle, and the magnet parts 31 shorter than the magnet part 31 at the middle are arranged in twos at the two ends of the magnet part at the middle.

In addition, oblong magnets (long magnets) are located at the two ends in the array direction of the magnet parts of each magnet unit 36 (the vertical direction in FIGS. 8A to 8D) so as to extend throughout the plurality of magnet units 36. These magnets are also the magnet parts 31. The magnets are also provided with the rotating shafts of rod-like magnets (not shown) along the horizontal direction in FIGS. 8A to 8D.

Note that in FIGS. 8A to 8D, “N” is written on each magnet part 31 acting as an N pole against the target in the ON state, and “S” is written on each magnet part 31 acting as an S pole against the target in the ON state. Each magnet part 31 on which nothing is written is in the OFF state.

Referring to FIG. 8A, the long magnet parts 31 located at the middle of the magnet units 36 on the third, seventh, and 11th rows from the left and the short magnet parts 31 of the same magnet units 36 which are located on the upper side in FIG. 8A are set to act as S poles against the target in the ON state. At this time, the respective magnet parts 31 which are adjacent to and surround these S poles are set in the OFF state.

In addition, the magnet parts 31 which are adjacent to and surround the magnet parts 31 in the OFF state are N poles in the ON state. That is, all the magnet parts 31 constituting the magnet units 36 on the first, fifth, ninth, and 13th columns from the left, the lowermost magnet parts 31 of the magnet units 36 on the second to fourth columns, sixth to eighth columns, and 10th to 12th columns from the left, and the oblong magnet part 31 on the upper side in FIG. 8A are set to act as N poles against the target in the ON state. The remaining magnet parts 31 are in the OFF state.

Setting the respective magnets in this state will cause the drift motion of electrons between the S poles and the N poles surrounding the S poles so as to form a closed loop. In this embodiment, as indicated by thick arrows 38 in FIG. 8A, the drift motion of electrons occurs to form three closed loops. Erosion is formed on the target 26 along these loops.

The magnet settings of the magnet parts 31 are sequentially changed as shown in FIGS. 8B to 8D to move the state in which some magnets act as S poles and other magnets surrounding them act as N poles against the target, to the right in FIGS. 8A and 8B, to the lower side in FIG. 8B and 8C, and to the left in FIGS. 8C and 8D.

The drift motions of electrons which form three closed loops are simultaneously moved by changing the set states of the magnets in this manner. This operation is repeated.

As described above, according to this embodiment, it is possible to form a plurality of closed loops of the drift motions of electrons even for a wide target and simultaneously move the loops. This can eliminate non-erosion regions on the target and implement uniform erosion.

### Fourth Embodiment

The fourth embodiment will be described next.

In magnetron sputtering using magnets, magnetic field adjustment is sometimes performed for a manufactured magnet to use it with the purpose of, for example, adjusting the thickness distribution of a film and improving a target utilization ratio. Conventionally, this magnetic field adjustment is performed by, for example, decreasing magnetic force by replacing a magnet, changing the shape of a magnet by machining it, or bonding a thin magnetic plate on the surface of a magnet.

It is known that, in general, deep erosion occurs in a portion on a target 26 in which a magnetic flux density component parallel to the target surface is large, and the vice versa.

Magnetic field adjustment using magnet parts 31 according to the present invention will be described below.

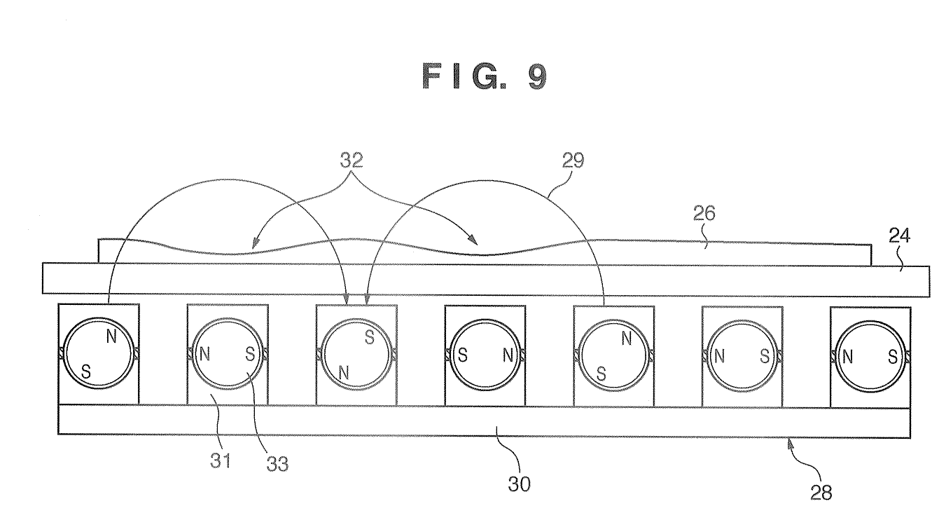

The magnet parts 31 according to the present invention allow the magnets to be turned on/off and can also adjust the strengths of the magnets to the magnetic flux densities between them. As shown in FIG. 9, when the rod-like magnets 33 are rotated and stopped in the middle state between ON and OFF at positions where the magnetic poles are tilted, the magnetic flux density on the target 26 becomes lower than that when the magnets are in the ON state. At this time, only the strength of a magnetic flux density component on the target 26 which is parallel to the target surface decreases, but the shape of magnetic lines of force 29 hardly changes. In a simple magnet structure including only rod-like magnets, when the magnetic poles of the magnets are stopped and tilted, both the magnetic flux density and the shape of magnetic lines of force simultaneously change.

In the state in FIG. 9, the first and fifth magnet parts 31 from the left in FIG. 9 act as weak N poles against the target 26, and the third magnet part 31 from the left in FIG. 9 acts as a weak S pole against the target 26. The remaining magnet parts 31 are in the OFF state.

Erosion regions 32 are formed centered on places where the magnetic lines of force 29 connecting such weak N poles and such a weak S pole are parallel to the target surface of the target 26. In this case, erosion is shallower than that formed when the magnet parts 31 are in the ON state.

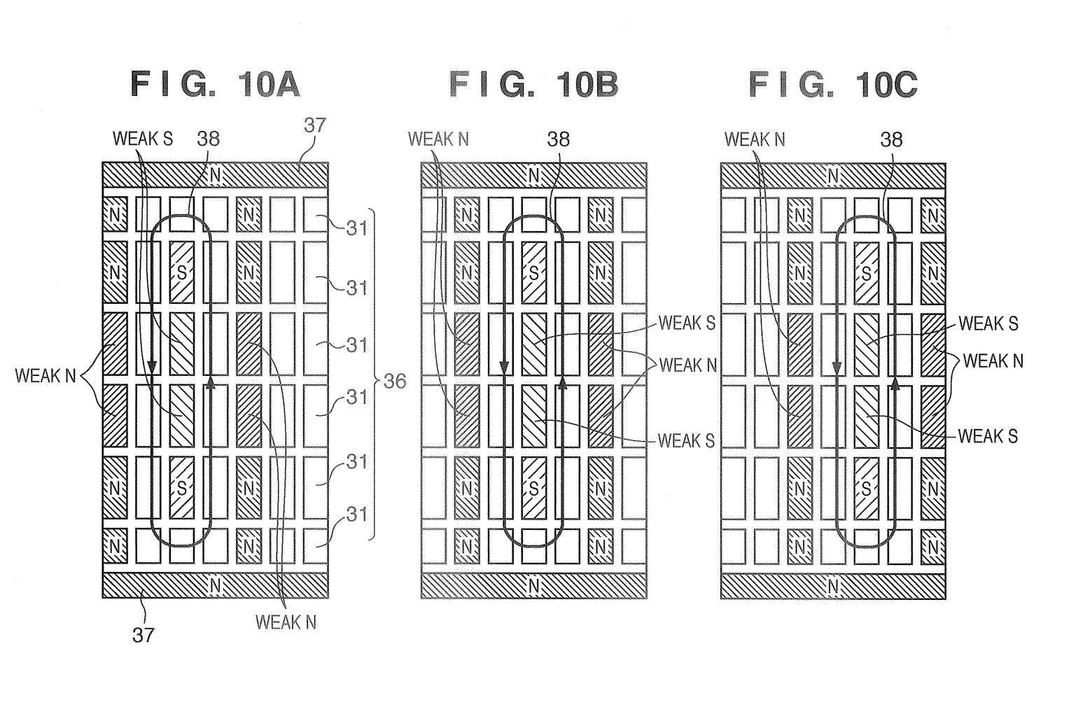

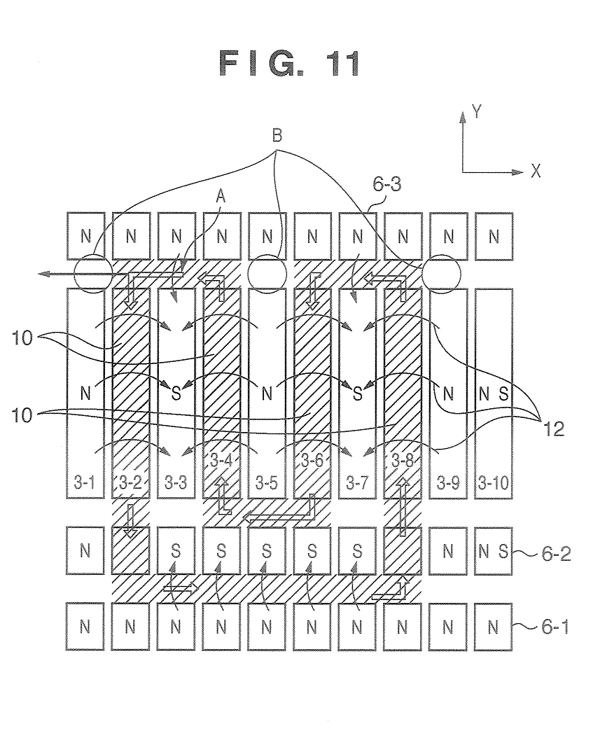

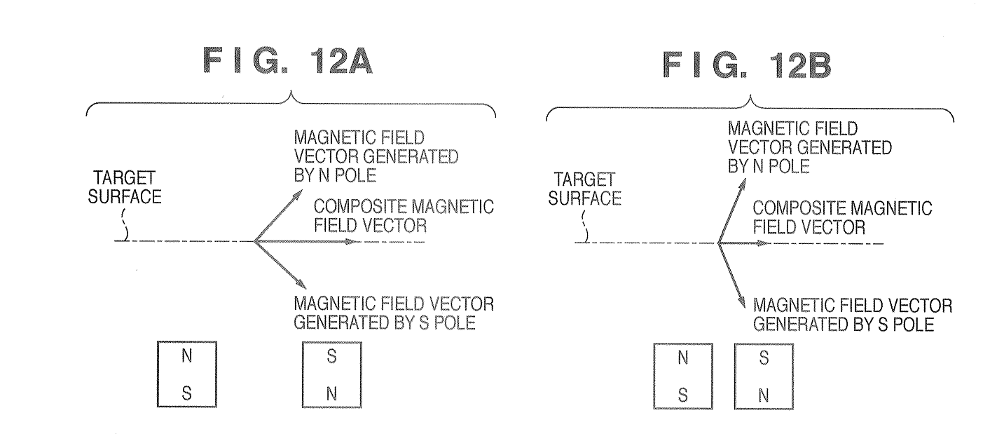

FIGS. 10A to 10C show an embodiment configured to adjust magnetic flux densities on the target 26 by using this characteristic.

As in the embodiment shown in FIGS. 6A to 6C, the fourth embodiment exemplifies a case in which erosion is moved in only the horizontal direction in FIGS. 10A to 10C. In the case in FIGS. 6A to 6C, the magnet unit 36 on each column has the three magnet parts 31 arranged in the vertical direction in FIGS. 6A to 6C. In the fourth embodiment, six magnet parts are arranged in the vertical direction.

The magnetic flux density generated by the magnet parts 31 constituting an arbitrary magnet unit 36 is adjusted in accordance with the rotational angles of the rod-like magnets. FIGS. 10A to 10C show a case in which the two magnet parts 31 located near the middle in the vertical direction in FIGS. 10A to 10C have weak magnetic force.

Referring to FIGS. 10A to 10C, “weak N” is written on each magnet part 31 acting as a weak N pole against the target, and “weak S” is written on each magnet part 31 acting as a weak S pole against the target. In addition, “N” or “S” is written on each magnet part 31 in the normal ON state, and nothing is written on each magnet part 31 in the OFF state.

When magnet settings are performed as shown in FIGS. 10A to 10C, erosion near the middle in the vertical direction in FIGS. 10A to 10C becomes shallow, and the remaining erosion becomes deep. The film formation rate in a substrate portion corresponding to the middle portion of the target in which the erosion speed is low is low, and the film formation rate in a substrate portion corresponding to a target end portion in which the erosion speed is high is high.

As in the cases in FIGS. 6A to 6C and FIGS. 8A to 8D, when the magnitude of a magnetic flux density is constant in the vertical direction of the magnet unit, since sputter particles fly to a substrate portion facing the middle portion of the target from all directions, the film formation rate becomes high. On the other hand, sputter particles fly to a substrate portion facing a target end portion only from one side, the film formation rate becomes low. As a result, the film thickness distribution within the substrate plane deteriorates.

Performing magnetic field adjustment in accordance with places on the target as in this embodiment can improve the film thickness distribution on the substrate.

According to the present invention, since it is possible to perform magnetic field adjustment in accordance with the rotation angles of the rod-like magnets of the magnet parts 31, magnetic field adjustment processing is facilitated.

In addition, as in this embodiment, an erosion region is almost uniformly formed on the entire surface of the target 26 by repeating the movement of the erosion region on the target 26 in the order of the state shown in FIG. 10A→the state shown in FIG. 10B→the state shown in FIG. 10C→the state shown in FIG. 10B→the state shown in FIG. 10A→the state shown in FIG. 10B→the state shown in FIG. 10C→ . . . . In this case, as is obvious, the techniques in the second and third embodiments can be applied to the fourth embodiment.

Furthermore, in this embodiment, rod-like magnets 33 are surrounded by a magnetic yoke 34. This decreases the magnetic flux density reaching the adjacent rod-like magnets 33. When the magnetic flux density in the rod-like magnet 33 temporally changes as the rod-like magnet 33 rotates, a so-called eddy current is induced. As a result, Joule heat is generated in the rod-like magnet 33. This decreases the magnetic force of the rod-like magnet 33. According to the present invention, however, since the magnetic flux density reaching the adjacent rod-like magnet 33 is decreased by the yoke 34, the influence of the above problem can be reduced.

Although the embodiments of the present invention have been described above with reference to the accompanying drawings, the embodiments can be changed as needed without departing from the technical idea of the present invention or being limited to the structures shown in the accompanying drawings.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2008-124678, filed May 12, 2008, and Japanese Patent Application No. 2009-106310, filed Apr. 24, 2009, which are hereby incorporated by reference herein in their entirety.

What is claimed is:

1. A magnetic field generating apparatus comprising:
a magnet assembly group including at least three magnet assemblies arranged along a straight line, each of the magnet assemblies including a permanent magnet, split yokes which are formed by magnetic members and are placed to surround an outer surface of the permanent magnet, and nonmagnetic members located between the yokes,
wherein one or two or more adjacent magnet assemblies constituting one magnet assembly group exhibit one polarity on one surface side,
a magnitude of a magnetic flux density on said one surface side which is generated by a surrounding magnet assembly which is adjacent to and surrounds said one or two or more adjacent magnet assemblies constituting said one magnet assembly group is smaller than a magnitude of a magnetic flux density on said one surface side which is generated by said one or two or more adjacent magnet assemblies constituting said one magnet assembly group, and
the surrounding magnet assembly which is adjacent to and surrounds said one or two or more adjacent magnet assemblies constituting said one magnet assembly group is adjacent to and surrounded by a magnet assembly or a permanent magnet which exhibits a polarity on said one surface side which is opposite to a polarity of said one or two or more magnet assemblies constituting said one magnet assembly group.

2. The apparatus according to claim 1, wherein said plurality of magnet assembly groups are arranged on the same plane parallel to said one surface, and the straight lines are parallel to each other, and
the permanent magnets are arranged at two end portions of said plurality of magnet assembly groups so as to intersect said one straight line.

3. The apparatus according to claim 1, further comprising
rotation means for independently rotating the permanent magnet in the magnet assembly about the straight line as a rotation axis,
detection means for detecting a magnetic flux density on said one surface side, and
control means for controlling rotation of said rotation means based on a detection result obtained by said detection means.

4. The apparatus according to claim 3, wherein said control means independently controls rotation of the permanent magnet in the magnet assembly.

5. The apparatus according to claim 3, wherein
said not less than six magnet assembly groups are arranged on the same plane parallel to said one surface with the straight lines being parallel to each other,
a cross relationship between magnetic fields is maintained among five adjacent magnet assembly groups of said not less than six magnet assembly groups by (i) making said one or two or more adjacent magnet assemblies constituting one magnet assembly group exhibit one polarity on one surface side, (ii) making a magnitude of a magnetic flux density on said one surface side which is generated by a surrounding magnet assembly which is adjacent to and surrounds said one or two or more magnet assemblies constituting said one magnet assembly group become smaller than a magnitude of a magnetic flux density on said one surface side which is generated by said one or two or more magnet assemblies constituting said one magnet assembly group, and (iii) making a surrounding magnet assembly surrounding said one or two or more adjacent magnet assemblies constituting said one magnet assembly group be adjacent to and surrounded by magnet assemblies or permanent magnets which exhibit, on said one surface side, a polarity opposite to a polarity of said one or two or more adjacent magnet assemblies constituting said one magnet assembly, and
said control means controls rotation of each of the permanent magnets of said not less than six magnet assembly groups so as to move a generated magnetic field on said one surface while maintaining a cross relationship between the magnet fields.

6. The apparatus according to claim 5, wherein said control means controls rotation of each of the permanent magnets of said not less than six magnet assembly groups so as to move a position of a magnetic field generated on said one surface along said one straight line while maintaining the cross relationship between the magnet fields.

7. The apparatus according to claim 1, wherein the permanent magnet has a cylindrical outer shape, and is magnetized at a predetermined angle relative to a plane passing through a center axis of the cylindrical shape.

8. The apparatus according to claim 7, wherein the predetermined angle is 90°.

9. The apparatus according to claim 1, wherein the yoke of a portion in contact with the nonmagnetic member has a thickness of not less than 2 mm, and a width of the nonmagnetic member corresponding to a gap between the split yokes is not more than 9 mm.

10. A sputtering apparatus comprising:
a magnetic field generating apparatus defined in claim 1;
target holding means, having one surface at which said magnetic field generating apparatus is placed, for holding a target on an opposite side to said one surface; and
substrate holding means for holding a substrate at a position facing the target.

11. A magnetic field generating method using a magnetic field generating apparatus including a magnet assembly group including at least three magnet assemblies arranged along a straight line, each of the magnet assemblies including a permanent magnet, split yokes which are formed by magnetic members and are placed to surround an outer surface of the permanent magnet, and nonmagnetic members located between the yokes, the method comprising steps of:
generating magnetic fields among five adjacent magnet assembly groups of not less than six magnet assembly groups; and
moving generation positions of the magnetic fields while maintaining a cross relationship between the magnetic fields generated in the step of generating,
wherein said cross relationship between magnetic fields is maintained among five adjacent magnet assembly groups by (i) making one or two or more magnet assemblies constituting one magnet assembly group exhibit one polarity on one surface side, (ii) making a magnitude of a magnetic flux density on said one surface side which is generated by a surrounding magnet assembly which is adjacent to and surrounds said one or two or more adjacent magnet assemblies constituting said one magnet assembly group become smaller than a magnitude of a magnetic flux density on said one surface side which is generated by said one or two or more magnet assemblies constituting said one magnet assembly group, and (iii) making a surrounding magnet assembly surrounding said one or two or more adjacent magnet assemblies constituting said one magnet assembly group be adjacent to and surrounded by magnet assemblies or permanent magnets which exhibit, on said one surface side, a polarity opposite to a polarity of said one or two or more adjacent magnet assemblies constituting said one magnet assembly group.

12. A method of manufacturing a device, the method comprising a step of processing a substrate by using a sputtering apparatus defined in claim 10.
